(19) United States
(12) Patent Application Publication
(10) Pub. No.: US 2025/0309907 A1
(43) Pub. Date: Oct. 2, 2025

(54) R-2R TYPE DAC AMPLIFIER FOR EARPHONES WITH VOLTAGE COMPENSATION FUNCTIONALITY

(71) Applicant: HIFIMAN KUNSHAN TECHNOLOGY GROUP CO., LTD, Kunshan (CN)

(72) Inventor: Fang BIAN, Kunshan (CN)

(21) Appl. No.: 19/086,023

(22) Filed: Mar. 20, 2025

(30) Foreign Application Priority Data
Mar. 26, 2024 (CN) 202410350113.8

(51) Int. Cl. H03M 1/10; H03M 1/06; H03M 1/78; H04R 3/04

(52) U.S. Cl. CPC H03M 1/1009; H03M 1/0602; H03M 1/785; H04R 3/04

(57) ABSTRACT

The present disclosure relates to an R-2R type DAC amplifier for earphones with voltage compensation functionality, integrating a voltage compensation feature. It uses a classic R-2R resistor network structure to convert digital signals to analog signals and achieves closed-loop feedback control through a precision voltage detection module, a voltage comparison module, and a voltage regulation control module, enabling real-time and accurate compensation of the output voltage. The device includes a calibration mode, wherein in the calibration mode, the system receives sweep digital signals across the overall frequencies and a full volume range and generates an error database. In a playback mode, whether for audio or video files, the system utilizes pre-stored error data to quickly adjust the output voltage, effectively reducing latency and enhancing analog signal output accuracy. This R-2R type DAC amplifier with voltage compensation functionality aims to overcome distortion and accuracy issues in traditional R-2R DACs, providing a higher-quality and more stable audio output experience.

### CROSS-REFERENCE TO RELATED APPLICATION

This application claims the priority to Chinese Patent Application No. 202410350113.8 filed on Mar. 26, 2024, which is incorporated herein by reference in its entirety.

### TECHNICAL FIELD

The present disclosure relates to the field of earphone amplifiers, specifically to an R-2R type DAC amplifier for earphones with voltage compensation functionality.

### BACKGROUND

The term “R-2R decoding” refers to an R-2R resistor ladder network decoding architecture, also known as ladder decoding (Ladder DAC) or R-2R Ladder DAC. This decoding circuit is composed of resistor combinations and utilizes logic switches to open and close logic gates corresponding to different bits based on input signals, causing current to pass through various resistor combinations and resulting in different output voltages. The advantage of R-2R decoding is that it requires far fewer resistors than traditional simple decoders. For example, a 24-bit decoder has 224 (i.e., 16777216) different output voltages. Using an R-2R architecture, only 48 resistors are needed. However, the performance of an R-2R architecture depends on the quality of the resistors, including the precision of resistor values. Therefore, designing an R-2R decoder as simple as this requires each resistor to have minimal deviation in resistance values to ensure accurate voltage output and, consequently, high-quality sound. Achieving such a large number of resistors with consistently low error levels is challenging, involving complex manufacturing processes and high production costs.

In R-2R digital-to-analog conversion, the analog waveform is represented as an amplitude signal, with half a quantization gradient as the accuracy error. This impact is less significant for large signals but becomes more pronounced and unavoidable with small signals, inevitably resulting in differential non-linear errors. Since these errors are related to the signal, they contribute to distortion. As the degree of non-linearity varies with signal amplitude, it is challenging to correct in post-processing. R-2R digital-to-analog conversion also unavoidably introduces zero-crossing distortion. Whenever the voltage on the most significant bit resistor changes (from 0 to 1 or vice versa), a shift in the output voltage polarity (from positive to negative or vice versa) occurs. Due to resistor errors and simultaneous switching within the resistor network, differential non-linear distortion and brief surges at the zero-crossing point can arise, resulting in zero-crossing distortion.

Therefore, how to achieve compensation for R-2R conversion is a critical issue for improving audio quality and urgently requires a solution.

### SUMMARY

In order to solve the above problems, the present disclosure provides an R-2R type DAC amplifier for earphones with voltage compensation functionality, including an R-2R algorithm module, an R-2R resistor network module, and a voltage compensation module.

The R-2R resistor network module is configured to convert digital signals into analog signals, thereby achieving digital-to-analog signal conversion, wherein the output analog voltage passes through a precision voltage detection module to reach the voltage compensation module;
the R-2R algorithm module includes an embedded R-2R algorithm that calculates, after a sweep digital signal is input into an error-free R-2R resistor network module, a theoretical voltage output of the error-free R-2R resistor network module based on the input digital signal;
the voltage compensation module compensates the actual output voltage of the R-2R resistor network module, by comparing the actual output voltage of the R-2R resistor network module with the theoretical voltage calculated by the R-2R algorithm module for the same input, and based on the comparison result, the compensated voltage is then output, thereby enabling the R-2R type DAC amplifier for earphones to operate with voltage compensation functionality.

Further, the DAC amplifier including an I2S audio interface, a precision timing control module, a precision voltage detection module, a voltage comparison module, a voltage regulation control module, and an output interface.

Further, the precision timing control module is connected to the I2S audio interface, the R-2R algorithm module, the R-2R resistor network module, the precision voltage detection module, the voltage comparison module, the voltage compensation module, and the voltage regulation control module, and the precision timing control module is configured to manage the timing control of the entire digital signal to ensure consistent timing for audio signal processing across each module;
the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
the voltage regulation control module is connected to the voltage compensation module, where both the voltage regulation control module and the voltage compensation module work to compensate the output voltage so that the compensated actual output voltage more closely matches the theoretical voltage value calculated by the R-2R algorithm module;
after compensating the output voltage of the R-2R resistor network module, the compensated voltage is output via the output interface.

Further, the R-2R resistor network module is a 16-bit, 24-bit, or 32-bit R-2R resistor network module.

Further, the timing control includes a two-step timing control process, specifically as follows:
after theoretical calculation is completed by the R-2R algorithm module, sampling of the actual output voltage of the R-2R resistor network begins via the precision voltage detection module, ensuring that the sampling moment is synchronized with the output voltage timing of the R-2R resistor network to obtain an accurate actual value;
a delay is set before the voltage compensation module to ensure that, after the voltage comparison module obtains the comparison result, the result is input into the voltage regulation control module, so that the adjusted voltage output from the voltage regulation control module is synchronized with the actual voltage in the voltage compensation module, thereby ensuring the accuracy of voltage compensation.

Further, the voltage comparison module outputs a voltage regulation digital signal for regulating the voltage, where the voltage regulation digital signal is a binary digital signal, after being input into the voltage regulation control module, the voltage regulation digital signal produces a compensation voltage for compensation;
upon entering the voltage compensation module, the compensation voltage is added to the output voltage of the R-2R resistor network module, thereby achieving compensation of the output voltage of the R-2R resistor network module.

Further, the voltage regulation control module includes a micro compensation resistor network, which is also structured in an R-2R configuration;
a reference voltage of the micro compensation resistor network is set to 12.5%, 25%, or 50% of the R-2R resistor network module's reference voltage, to ensure adjustment accuracy of the micro compensation resistor network when adjusting the output of the R-2R resistor network module;
alternatively,
the reference voltage of the micro compensation resistor network is the same as the reference voltage of the R-2R resistor network module, and the output voltage of the micro compensation resistor network is reduced to 12.5%, 25%, or 50% through a voltage divider circuit, to ensure adjustment accuracy of the micro compensation resistor network when adjusting the output of the R-2R resistor network module.

Further, the voltage regulation control module includes a current-steering DAC.

A reference voltage of the current-steering DAC is set to 12.5%, 25%, or 50% of the R-2R resistor network module's reference voltage, to ensure adjustment accuracy when adjusting the output of the R-2R resistor network module by the current-steering DAC;
alternatively,
the reference voltage of the current-steering DAC is the same as the reference voltage of the R-2R resistor network module, and after the voltage output by the current-steering DAC, the output voltage of the micro compensation resistor network is reduced to 12.5%, 25%, or 50% by a voltage divider circuit, ensuring adjustment accuracy when adjusting the output of the R-2R resistor network module by the current-steering DAC.

Further, the voltage regulation control module is equipped with two sets of compensation capacitors and two sets of compensation switches, one set of compensation capacitors is used to raise the output voltage, while the other set of compensation capacitors is used to lower the output voltage, each set of compensation capacitors corresponds to a set of control switches;
based on the output result of the voltage comparison module, one of two sets of the control switch is opened or closed, and
the number of switches opened in each set is controlled, thereby outputting a compensation voltage for adjustment;
upon entering the voltage compensation module, the compensation voltage is added to the output voltage of the R-2R resistor network module, thereby achieving compensation of the output voltage of the R-2R resistor network module.

Further, the R-2R algorithm module is implemented using a DSP chip, specifically a TMS320C28 series real-time microcontroller, which includes an independent clock controller;
additionally, the voltage comparison module is integrated into the TMS320C28 series real-time microcontroller.

Further, a FIFO buffer is disposed within the I2S audio interface to ensure that the received data is synchronized with the sampling rate of the R-2R;
an additional FIFO buffer is disposed before the voltage compensation module to ensure that, after the voltage comparison module obtains the comparison result, the result is input into the voltage regulation control module, so that the output adjusted voltage of the voltage regulation control module is synchronized with the actual voltage of the voltage compensation module, thereby ensuring the accuracy of voltage compensation.

Further, an operating method for the R-2R type DAC amplifier for earphones with voltage compensation functionality.

A working mode of the DAC amplifier includes a calibration mode and a playback mode,
where the DAC amplifier performs self-calibration in the calibration mode and the DAC amplifier performs audio playback in the playback mode, the playback mode includes an audio file playback mode and a video file playback mode, the calibration mode and the playback mode are selected through a human-computer interaction interface and are not executed simultaneously;
The calibration mode includes the following steps.
Step A1: selecting the calibration mode, the DAC amplifier confirms that the current working mode is the calibration mode according to the human-computer interaction interface.
Step A2: the I2S audio interface receives an externally input sweep digital signal, which includes multiple sets of digital audio signals of varying volumes and different frequencies, the volume range of the sweep digital signal covers the maximum volume and the minimum volume of the DAC amplifier, and the frequency range of the sweep digital signal covers the minimum frequency and the maximum frequency that the DAC amplifier can handle, each set of signals in the sweep digital signal lasts for a period.
Step A3: the R-2R resistor network module is configured to convert the sweep digital signals into analog signals, thereby achieving digital-to-analog signal conversion, wherein the output analog voltage passes through a precision voltage detection module to reach the voltage compensation module;
the R-2R algorithm module includes an embedded R-2R algorithm that calculates, after a sweep digital signal is input into an error-free R-2R resistor network module, a theoretical voltage output of the error-free R-2R resistor network module based on the sweep digital signal input.
Step A4, the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
simultaneously, the voltage comparison module records a one-to-one correspondence between the current data input from the R-2R algorithm module and the data output by the voltage comparison module.
Step A5: Steps A3 and A4 are performed for all sweep digital signals to obtain a one-to-one correspondence between all data input into the R-2R algorithm module and the data output from the voltage comparison module, thereby completing the calibration;
the playback mode includes the following steps:
selecting the playback mode, the DAC amplifier confirms that the current working mode is in the playback mode via the human-computer interaction interface and further identifies whether it is in the audio playback mode or in the video playback mode;
in a case that it is in the video playback mode:
the I2S audio interface receives an externally input digital audio signal, the R-2R resistor network module converts the sweep digital signal into an analog signal, thereby achieving digital-to-analog conversion, wherein the output analog voltage passes through the precision voltage detection module to reach the voltage compensation module;
the R-2R algorithm embedded in the R-2R algorithm module calculates the theoretical voltage that would be output if the sweep digital signal were input into an error-free R-2R resistor network module; the theoretical voltage value calculated by the R-2R algorithm module is then input into the voltage comparison module;
the voltage comparison module, based on the one-to-one correspondence between the data input into the R-2R algorithm module and the data output from the voltage comparison module, directly obtains the difference between the output signal voltage of the R-2R resistor network module and the theoretical voltage calculated by the R-2R algorithm module, and transmits the difference to the voltage regulation control module;
the voltage regulation control module is connected to the voltage compensation module, the voltage regulation control module and the voltage compensation module compensate the output voltage, so that the actual output voltage after compensation more closely matches the theoretical voltage value calculated by the R-2R algorithm module, thereby reducing the delay caused during voltage detection and voltage comparison;
after compensating the output voltage of the R-2R resistor network module, the compensated voltage is output via the output interface;
in a case that it is in the audio playback mode:
the I2S audio interface receives an externally input digital audio signal, the R-2R resistor network module converts the sweep digital signal into an analog signal, thereby achieving digital-to-analog conversion, wherein the output analog voltage passes through the precision voltage detection module to reach the voltage compensation module;
the R-2R algorithm module includes an embedded R-2R algorithm that calculates, after a sweep digital signal is input into an error-free R-2R resistor network module, a theoretical voltage output of the error-free R-2R resistor network module based on the sweep digital signal input;
the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
the voltage regulation control module is connected to the voltage compensation module, the voltage regulation control module and the voltage compensation module compensate the output voltage, so that the actual output voltage after compensation more closely matches the theoretical voltage value calculated by the R-2R algorithm module, thereby reducing the delay caused during voltage detection and voltage comparison;
after compensating the output voltage of the R-2R resistor network module, the compensated voltage is output via the output interface.

The beneficial effects of the present disclosure are as follows.

Overall, the R-2R type DAC amplifier for earphones with voltage compensation functionality provided by the invention not only achieves high-quality conversion from digital to analog signals but also, according to a precise closed-loop feedback mechanism and an optimized hardware design, significantly reduces distortion caused by resistor inaccuracies or other factors, thereby enhancing audio playback quality and user experience.

The device of the present disclosure provides high-precision analog output. according to real-time comparison and compensation, the actual output voltage more closely approximates the theoretical calculated value, significantly improving the accuracy and linearity of audio signal conversion. A closed-loop control system is established using the precision voltage detection module, the voltage comparison module, and the voltage regulation control module ensuring the system's stability and accuracy. The precision timing control module ensures consistency and synchronization in digital audio data processing across all modules, preventing audio quality degradation caused by timing mismatches. Different methods (such as micro compensation resistor networks, current-steering DACs, or capacitor switch combinations) are used for voltage compensation, providing precise and efficient compensation schemes based on actual conditions. The algorithm module is implemented using a TMS320C28 series DSP chip, which integrates key components to ensure high-speed computational ability and real-time performance. A FIFO buffer is provided in the I2S audio interface to maintain synchronization between digital audio data and the R-2R sampling rate, effectively preventing data loss and jitter issues.

Additionally, the R-2R type DAC amplifier in the invention features a unique calibration mode. By receiving and processing sweep digital signals that cover the overall frequencies and a full volume range, the system can perform precise self-calibration, ensuring output accuracy across different frequencies and volumes. During calibration, a one-to-one correspondence between the input data of the R-2R algorithm module and the output data of the voltage comparison module is recorded. This pre-stored relationship is directly used for voltage compensation in the playback mode, avoiding delays associated with real-time calculations and improving playback efficiency.

The present disclosure supports both audio file playback mode and video file playback mode, with convenient mode-switching via the human-computer interaction interface, enhancing the device's flexibility and broadening its application scenarios. For video playback, the one-to-one correspondence can be directly utilized to reduce latency, while in audio playback, real-time voltage difference calculations provide high-precision compensation.

### BRIEF DESCRIPTION OF THE DRAWINGS

In order to explain the embodiments of the present disclosure or the technical solutions in the prior art more clearly, a brief description will be given below with reference to the accompanying drawings which are used in the description of the embodiments or the prior art and it is obvious that the drawings in the description below are only some embodiments of the present disclosure, and it would be obvious for a person skilled in the art to obtain other drawings according to these drawings without involving any inventive effort.

FIG. 1 is a schematic diagram of the overall architecture of the present disclosure.

FIG. 2 is a schematic diagram of an R-2R resistor network structure according to the present disclosure.

FIG. 3 is a schematic diagram of a current-steering DAC structure according to the present disclosure.

### DETAILED DESCRIPTION

### Embodiment 1

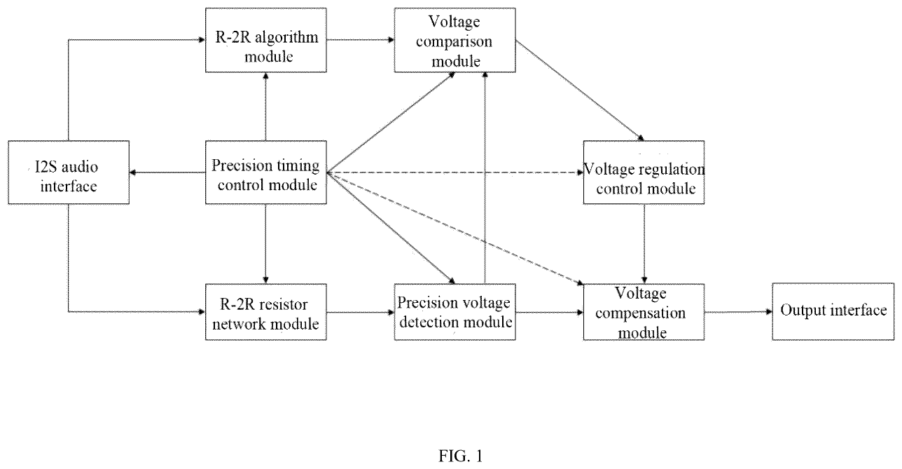

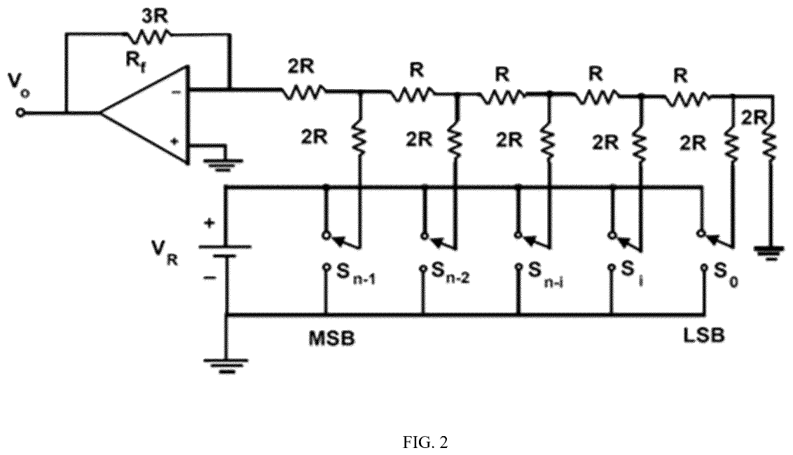

Referring to FIGS. 1 and 2, the present disclosure provides an R-2R type DAC amplifier for earphones with voltage compensation functionality, including an R-2R algorithm module, an R-2R resistor network module, and a voltage compensation module.

A typical R-2R resistor network module is shown in FIG. 2. The R-2R resistor network module is configured to convert digital signals into analog signals, thereby achieving digital-to-analog signal conversion, wherein the output analog voltage passes through a precision voltage detection module to reach the voltage compensation module;
the R-2R algorithm module includes an embedded R-2R algorithm that calculates, after a sweep digital signal is input into an error-free R-2R resistor network module, a theoretical voltage output of the error-free R-2R resistor network module based on the input digital signal, assuming the theoretical voltage output is processed by an ideal and error-free R-2R resistor network module;
the voltage compensation module compensates the actual output voltage of the R-2R resistor network module, by comparing the actual output voltage of the R-2R resistor network module with the theoretical voltage calculated by the R-2R algorithm module for the same input, and based on the comparison result, the compensated voltage is then output, thereby enabling the R-2R type DAC amplifier for earphones to operate with voltage compensation functionality.

Further, the DAC amplifier including an I2S audio interface, a precision timing control module, a precision voltage detection module, a voltage comparison module, a voltage regulation control module, and an output interface.

Further, the precision timing control module is connected to the I2S audio interface, the R-2R algorithm module, the R-2R resistor network module, the precision voltage detection module, the voltage comparison module, the voltage compensation module, and the voltage regulation control module, and the precision timing control module is configured to manage the timing control of the entire digital signal to ensure consistent timing for audio signal processing across each module;
the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
the voltage regulation control module is connected to the voltage compensation module, where both the voltage regulation control module and the voltage compensation module work to compensate the output voltage so that the compensated actual output voltage more closely matches the theoretical voltage value calculated by the R-2R algorithm module;
after compensating the output voltage of the R-2R resistor network module, the compensated voltage is output via the output interface.

Further, the R-2R resistor network module is a 16-bit, 24-bit, or 32-bit R-2R resistor network module.

Further, the timing control includes a two-step timing control process, specifically as follows:
after theoretical calculation is completed by the R-2R algorithm module, sampling of the actual output voltage of the R-2R resistor network begins through the precision voltage detection module, ensuring that the sampling moment is synchronized with the output voltage timing of the R-2R resistor network to obtain an accurate actual value;
a delay is set before the voltage compensation module to ensure that, after the voltage comparison module obtains the comparison result, the result is input into the voltage regulation control module, so that the adjusted voltage output from the voltage regulation control module is synchronized with the actual voltage in the voltage compensation module, thereby ensuring the accuracy of voltage compensation.

Further, the voltage comparison module outputs a voltage regulation digital signal for regulating the voltage, where the voltage regulation digital signal is a binary digital signal, after being input into the voltage regulation control module, the voltage regulation digital signal produces a compensation voltage for compensation;
upon entering the voltage compensation module, the compensation voltage is added to the output voltage of the R-2R resistor network module, thereby achieving compensation of the output voltage of the R-2R resistor network module.

Further, the voltage regulation control module includes a micro compensation resistor network, which is also structured in an R-2R configuration,
a reference voltage of the micro compensation resistor network is set to 12.5%, 25%, or 50% of the R-2R resistor network module's reference voltage, to ensure adjustment accuracy of the micro compensation resistor network when adjusting the output of the R-2R resistor network module;
further, the R-2R algorithm module is implemented using a DSP chip, specifically a TMS320C28 series real-time microcontroller, which includes an independent clock controller;
additionally, the voltage comparison module is integrated into the TMS320C28 series real-time microcontroller.

Further, a FIFO buffer is disposed within the I2S audio interface to ensure that the received data is synchronized with the sampling rate of the R-2R;
an additional FIFO buffer is disposed before the voltage compensation module to ensure that, after the voltage comparison module obtains the comparison result, the result is input into the voltage regulation control module, so that the output adjusted voltage of the voltage regulation control module is synchronized with the actual voltage of the voltage compensation module, thereby ensuring the accuracy of voltage compensation.

Wherein, the specific R-2R algorithm implemented using a DSP can be as follows:

```
    #include<stdio.h>
        #include<stdbool.h>
    typedef struct{
        float resistances[2]; //resistance value array for R and 2R
        int bits; //number of bits of DAC
        float vref; //reference voltage
    }R2RDAC;
    unsigned long get_pcm_sample_from_i2s(void);
    void set_DAC_output(float voltage);
    bool is_i2s_data_available(void);
        float R2R_convert(R2RDAC*dac, unsigned long binary_code){
        float total_resistance=(float)(dac->resistances[0]+dac->resistances[1])*
(1<<(dac->bits-1));
        float voltage out=0.0f;
        for(int i=0; i<vdac->bits; i++){
            if((binary_code>>»i)&1)
                voltage_out+=dac->resistances[i%2]/total_resistance;
            }
        return voltage_out;
        }
      void process_audio_data(R2RDAC*dac){
        while(true){
        //wait for I2S data to be available
        while(!is_i2s_data_available( )){ }
                //obtain a next PCM sample
        unsigned long pcm_sample=get_pcm_sample_from_i2s( );
        //convert 32-bit PCM samples to 32-bit binary code (herein the I2S data are already 32
bits)
        unsigned long binary_code=pcm_sample;
        //convert binary code to analog voltage
        float voltage=R2R_convert(dac,binary_code);
        //set DAC output
            set_DAC_output(voltage);
      }
    }
    int main( ){
        R2RDAC dac={{1.0f, 2.0f}, 32, 5.0f}; //initialize a 32-bit R2R DAC
        //start processing audio data
        process_audio_data(&dac);
        return 0;
    }
```

The above program example is merely an algorithm instance for DSP; the algorithm may vary for different DSP chips.

### Embodiment 2

The example shares the same components as Embodiment 1, with the difference being that the reference voltage of the micro compensation resistor network is the same as the reference voltage of the R-2R resistor network module, and after the micro compensation resistor network outputs a voltage, the micro compensation resistor network's output voltage is reduced to 12.5%, 25%, or 50% through a voltage divider circuit, to ensure adjustment accuracy of the micro compensation resistor network when adjusting the output of the R-2R resistor network module.

### Embodiment 3

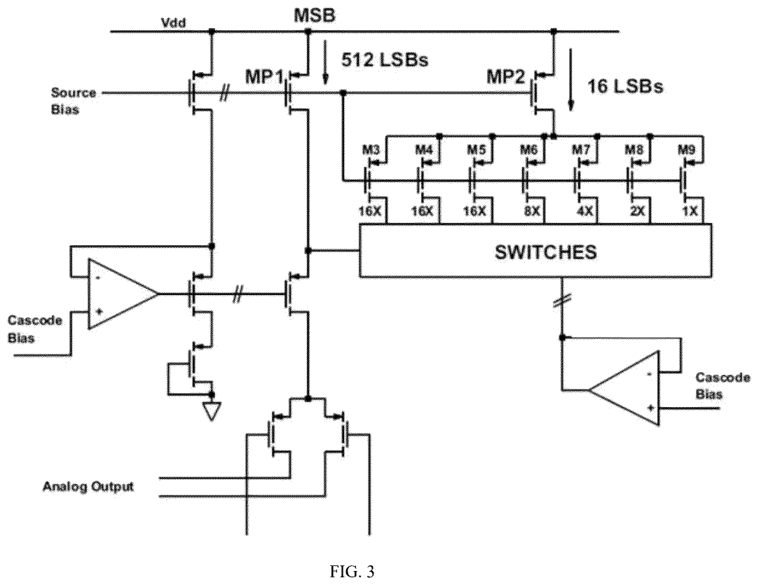

Referring to FIG. 3, the embodiment shares the same components as Embodiment 1, with the difference being that the voltage regulation control module includes a current-steering DAC.

A reference voltage of the current-steering DAC is set to 12.5%, 25%, or 50% of the R-2R resistor network module's reference voltage, to ensure adjustment accuracy of the current-steering DAC when adjusting the output of the R-2R resistor network module.

### Embodiment 4

The embodiment shares the same components as Embodiment 3, with the difference being that the reference voltage of the current-steering DAC is the same as the reference voltage of the R-2R resistor network module, and after the voltage output by the current-steering DAC passes through a voltage divider circuit, the output voltage of the micro compensation resistor network is reduced to 12.5%, 25%, or 50%, ensuring an accuracy of the current-steering DAC when adjusting the output of the R-2R resistor network module.

### Embodiment 5

The embodiment shares the same components as Embodiment 1, with the difference being that the voltage regulation control module is equipped with two sets of compensation capacitors and two sets of compensation switches, one set of compensation capacitors is used to raise the output voltage, while the other set of compensation capacitors is used to lower the output voltage, each set of compensation capacitors corresponds to a set of control switches.

Based on the output result of the voltage comparison module, one of two sets of the control switch is opened or closed, and the number of switches opened in each set is controlled, thereby outputting a compensation voltage for adjustment;
upon entering the voltage compensation module, the compensation voltage is added to the output voltage of the R-2R resistor network module, thereby achieving compensation of the output voltage of the R-2R resistor network module.

### Embodiment 6

The embodiment protects an operating method for the R-2R type DAC amplifier for earphones with voltage compensation functionality.

A working mode of the DAC amplifier includes a calibration mode and a playback mode, where the DAC amplifier performs self-calibration in the calibration mode and the DAC amplifier performs audio playback in the playback mode, the playback mode includes an audio file playback mode and a video file playback mode, the calibration mode and the playback mode are selected via a human-computer interaction interface and are not executed simultaneously;
The calibration mode includes the following steps.
Step A1: selecting the calibration mode, the DAC amplifier confirms that the current working mode is the calibration mode according to the human-computer interaction interface;
Step A2: the I2S audio interface receives an externally input sweep digital signal, which includes multiple sets of digital audio signals of varying volumes and different frequencies, the volume range of the sweep digital signal covers the maximum volume and the minimum volume of the DAC amplifier, and the frequency range of the sweep digital signal covers the minimum frequency and the maximum frequency that the DAC amplifier can handle, each set of signals in the sweep digital signal lasts for a period.
Step A3: the R-2R resistor network module is configured to convert the sweep digital signals into analog signals, thereby achieving digital-to-analog signal conversion, wherein the output analog voltage passes through a precision voltage detection module to reach the voltage compensation module;
the R-2R algorithm module includes an embedded R-2R algorithm that calculates, after a sweep digital signal is input into an error-free R-2R resistor network module, a theoretical voltage output of the error-free R-2R resistor network module based on the sweep digital signal input.
Step A4: the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
simultaneously, the voltage comparison module records a one-to-one correspondence between the current data input from the R-2R algorithm module and the data output by the voltage comparison module.
Step A5: Steps A3 and A4 are performed for all sweep digital signals to obtain a one-to-one correspondence between all data input into the R-2R algorithm module and the data output from the voltage comparison module, thereby completing the calibration;
the playback mode includes the following steps:
selecting the playback mode, the DAC amplifier confirms that the current working mode is in the playback mode via the human-computer interaction interface and further identifies whether it is in the audio playback mode or in the video playback mode;
in a case that it is in the video playback mode:
the I2S audio interface receives an externally input digital audio signal, the R-2R resistor network module converts the sweep digital signal into an analog signal, thereby achieving digital-to-analog conversion, wherein the output analog voltage passes through the precision voltage detection module to reach the voltage compensation module;
the R-2R algorithm embedded in the R-2R algorithm module calculates the theoretical voltage that would be output if the sweep digital signal were input into an error-free R-2R resistor network module; the theoretical voltage value calculated by the R-2R algorithm module is then input into the voltage comparison module;
the voltage comparison module, based on the one-to-one correspondence between the data input into the R-2R algorithm module and the data output from the voltage comparison module, directly obtains the difference between the output signal voltage of the R-2R resistor network module and the theoretical voltage calculated by the R-2R algorithm module, and transmits the difference to the voltage regulation control module;
the voltage regulation control module is connected to the voltage compensation module, the voltage regulation control module and the voltage compensation module compensate the output voltage, so that the actual output voltage after compensation more closely matches the theoretical voltage value calculated by the R-2R algorithm module, thereby reducing the delay caused during voltage detection and voltage comparison;
after compensating the output voltage of the R-2R resistor network module, the compensated voltage is output via the output interface;
in a case that it is in the audio playback mode:
the I2S audio interface receives an externally input digital audio signal, the R-2R resistor network module converts the sweep digital signal into an analog signal, thereby achieving digital-to-analog conversion, wherein the output analog voltage passes through the precision voltage detection module to reach the voltage compensation module;
the R-2R algorithm module includes an embedded R-2R algorithm that calculates, after a sweep digital signal is input into an error-free R-2R resistor network module, a theoretical voltage output of the error-free R-2R resistor network module based on the sweep digital signal input;
the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
the voltage regulation control module is connected to the voltage compensation module, the voltage regulation control module and the voltage compensation module compensate the output voltage, so that the actual output voltage after compensation more closely matches the theoretical voltage value calculated by the R-2R algorithm module, thereby reducing the delay caused during voltage detection and voltage comparison;
after compensating the output voltage of the R-2R resistor network module, the compensated voltage is output via the output interface.

The foregoing description of the embodiments has been presented for purposes of illustration and description. It is not intended to be exhaustive or to limit the disclosure. Individual elements or features of a particular embodiment are generally not limited to the particular embodiment, but, where applicable, may be interchanged and used in a selected embodiment even if not specifically shown or described. The same elements or features may also vary in many ways. Such variations are not to be regarded as a departure from the present disclosure, and all such modifications are intended to be included within the scope of the present disclosure.

Example embodiments are provided so that this disclosure will be thorough and will fully convey the scope to those skilled in the art. Numerous details are set forth, such as examples of specific parts, devices, and methods, in order to provide a thorough understanding of the embodiments of the present disclosure. It will be apparent to those skilled in the art that specific details need not be used, that the example embodiments may be implemented in many different forms, and that neither should be construed to limit the scope of the present disclosure. In certain example embodiments, well-known procedures, well-known device structures, and well-known techniques are not described in detail.

Herein, specific terminology is used for the purpose of describing particular example embodiments only and is not intended to be limiting. As used herein, the singular forms “a”, “an” and “the” are intended to include the plural forms as well, unless the context clearly indicates to the contrary. The terms “including” and “having” are inclusive and thus specify the presence of the stated features, integers, steps, operations, elements, and/or components, but do not preclude the presence or addition of one or more other features, integers, steps, operations, elements, components, and/or groups thereof. Unless the order of execution is explicitly indicated, the method steps, processes, and operations described herein are not to be construed as necessarily requiring execution in the particular order discussed and illustrated. It should also be understood that additional or alternative steps may be employed.

1. An R-2R type DAC amplifier for earphones with voltage compensation functionality, comprising an R-2R algorithm module, an R-2R resistor network module, and a voltage compensation module, wherein:
the R-2R resistor network module is configured to convert digital signals into analog signals, thereby achieving digital-to-analog signal conversion, wherein the output analog voltage passes through a precision voltage detection module to reach the voltage compensation module;
the R-2R algorithm module comprises an embedded R-2R algorithm that calculates, after a sweep digital signal is input into an error-free R-2R resistor network module, a theoretical voltage output of the error-free R-2R resistor network module based on the input digital signal;
the voltage compensation module compensates the actual output voltage of the R-2R resistor network module, by comparing the actual output voltage of the R-2R resistor network module with the theoretical voltage calculated by the R-2R algorithm module for the same input, and based on the comparison result, the compensated voltage is then output, thereby enabling the R-2R type DAC amplifier for earphones to operate with voltage compensation functionality.

2. The R-2R type DAC amplifier for earphones with voltage compensation functionality according to claim 1, further comprising an I2S audio interface, a precision timing control module, a precision voltage detection module, a voltage comparison module, a voltage regulation control module, and an output interface, the precision timing control module is connected to the I2S audio interface, the R-2R algorithm module, the R-2R resistor network module, the precision voltage detection module, the voltage comparison module, the voltage compensation module, and the voltage regulation control module, and the precision timing control module is configured to manage the timing control of the entire digital signal to ensure consistent timing for audio signal processing across each module;
the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
the voltage regulation control module is connected to the voltage compensation module, where both the voltage regulation control module and the voltage compensation module work to compensate the output voltage so that the compensated actual output voltage more closely matches the theoretical voltage value calculated by the R-2R algorithm module;
after compensating the voltage output from the R-2R resistor network module, the voltage is output via the output interface.

3. The R-2R type DAC amplifier for earphones with voltage compensation functionality according to claim 1, wherein the R-2R resistor network module is a 16-bit, 24-bit, or 32-bit R-2R resistor network module.

4. The R-2R type DAC amplifier for earphones with voltage compensation functionality according to claim 2, wherein:
the timing control comprises a two-step timing control process, specifically as follows:
after theoretical calculation is completed by the R-2R algorithm module, sampling of the actual output voltage of the R-2R resistor network begins through the precision voltage detection module, ensuring that the sampling moment is synchronized with the output voltage timing of the R-2R resistor network to obtain an accurate actual value; a delay is set before the voltage compensation module to ensure that, after the voltage comparison module obtains the comparison result, the result is input into the voltage regulation control module, so that the adjusted voltage output from the voltage regulation control module is synchronized with the actual voltage in the voltage compensation module, thereby ensuring the accuracy of voltage compensation.

5. The R-2R type DAC amplifier for earphones with voltage compensation functionality according to claim 4, wherein the voltage comparison module outputs a voltage regulation digital signal for regulating the voltage, where the voltage regulation digital signal is a binary digital signal, after being input into the voltage regulation control module, the voltage regulation digital signal produces a compensation voltage for compensation;
upon entering the voltage compensation module, the compensation voltage is added to the output voltage of the R-2R resistor network module, thereby achieving compensation of the output voltage of the R-2R resistor network module.

6. The R-2R type DAC amplifier for earphones with voltage compensation functionality according to claim 5, wherein the voltage regulation control module comprises a micro compensation resistor network, which is also structured in an R-2R configuration,
a reference voltage of the micro compensation resistor network is set to 12.5%, 25%, or 50% of the R-2R resistor network module's reference voltage, to ensure adjustment accuracy of the micro compensation resistor network when adjusting the output of the R-2R resistor network module;
alternatively,
the reference voltage of the micro compensation resistor network is the same as the reference voltage of the R-2R resistor network module, and the output voltage of the micro compensation resistor network is reduced to 12.5%, 25%, or 50% through a voltage divider circuit, to ensure adjustment accuracy of the micro compensation resistor network when adjusting the output of the R-2R resistor network module.

7. The R-2R type DAC amplifier for earphones with voltage compensation functionality according to claim 5, wherein the voltage regulation control module comprises a current-steering digital-to-analog converter (DAC),
a reference voltage of the current-steering DAC is set to 12.5%, 25%, or 50% of the R-2R resistor network module's reference voltage, to ensure adjustment accuracy of the current-steering DAC when adjusting the output of the R-2R resistor network module;
alternatively,
the reference voltage of the current-steering DAC is the same as the reference voltage of the R-2R resistor network module, and after the voltage output by the current-steering DAC, the output voltage of the micro compensation resistor network is reduced to 12.5%, 25%, or 50% by a voltage divider circuit, ensuring adjustment accuracy when adjusting the output of the R-2R resistor network module by the current-steering DAC.

8. The R-2R type DAC amplifier for earphones with voltage compensation functionality according to claim 4, wherein the voltage regulation control module is equipped with two sets of compensation capacitors and two sets of compensation switches, one set of compensation capacitors is used to raise the output voltage, while the other set of compensation capacitors is used to lower the output voltage, each set of compensation capacitors corresponds to a set of control switches;
based on the output result of the voltage comparison module, one of two sets of the control switch is opened or closed, and the number of switches opened in each set is controlled, thereby outputting a compensation voltage for adjustment;
upon entering the voltage compensation module, the compensation voltage is added to the output voltage of the R-2R resistor network module, thereby achieving compensation of the output voltage of the R-2R resistor network module.

9. The R-2R type DAC amplifier for earphones with voltage compensation functionality according to claim 2, wherein the R-2R algorithm module is implemented using a DSP chip, specifically a TMS320C28 series real-time microcontroller, which comprises an independent clock controller,
additionally, the voltage comparison module is integrated into the TMS320C28 series real-time microcontroller;
a FIFO buffer is disposed within the I2S audio interface to ensure that the received data is synchronized with the sampling rate of the R-2R;
an additional FIFO buffer is disposed before the voltage compensation module to ensure that, after the voltage comparison module obtains the comparison result, the result is input into the voltage regulation control module, so that the output adjusted voltage of the voltage regulation control module is synchronized with the actual voltage of the voltage compensation module, thereby ensuring the accuracy of voltage compensation.

10. An operating method of an R-2R type DAC amplifier for earphones with voltage compensation functionality, according to claim 1, wherein:
a working mode of the DAC amplifier comprises a calibration mode and a playback mode, where the DAC amplifier performs self-calibration in the calibration mode and the DAC amplifier performs audio playback in the playback mode, the playback mode comprises an audio file playback mode and a video file playback mode, the calibration mode and the playback mode are selected through a human-computer interaction interface and are not executed simultaneously,
the calibration mode comprises the following steps:
step A1: selecting the calibration mode, the DAC amplifier confirms that the current working mode is the calibration mode according to the human-computer interaction interface;
step A2: the I2S audio interface receives an externally input sweep digital signal, which comprises multiple sets of digital audio signals of varying volumes and different frequencies, the volume range of the sweep digital signal covers the maximum volume and the minimum volume of the DAC amplifier, and the frequency range of the sweep digital signal covers the minimum frequency and the maximum frequency that the DAC amplifier can handle, each set of signals in the sweep digital signal lasts for a period;
step A3: the R-2R resistor network module is configured to convert the sweep digital signals into analog signals, thereby achieving digital-to-analog signal conversion, wherein the output analog voltage passes through a precision voltage detection module to reach the voltage compensation module;
the R-2R algorithm module comprises an embedded R-2R algorithm that calculates, after a sweep digital signal is input into an error-free R-2R resistor network module, a theoretical voltage output of the error-free R-2R resistor network module based on the sweep digital signal input;
step 4: the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
simultaneously, the voltage comparison module records a one-to-one correspondence between the current data input from the R-2R algorithm module and the data output by the voltage comparison module;
step A5: Steps A3 and A4 are performed for all sweep digital signals to obtain a one-to-one correspondence between all data input into the R-2R algorithm module and the data output from the voltage comparison module, thereby completing the calibration;
the playback mode comprises the following steps:
selecting the playback mode, the DAC amplifier confirms that the current working mode is in the playback mode via the human-computer interaction interface and further identifies whether it is in the audio playback mode or in the video playback mode;
in a case that it is in the video playback mode:
the I2S audio interface receives an externally input digital audio signal, the R-2R resistor network module converts the sweep digital signal into an analog signal, thereby achieving digital-to-analog conversion, wherein the output analog voltage passes through the precision voltage detection module to reach the voltage compensation module;
the R-2R algorithm embedded in the R-2R algorithm module calculates the theoretical voltage that would be output if the sweep digital signal were input into an error-free R-2R resistor network module; the theoretical voltage value calculated by the R-2R algorithm module is then input into the voltage comparison module;
the voltage comparison module, based on the one-to-one correspondence between the data input into the R-2R algorithm module and the data output from the voltage comparison module, directly obtains the difference between the output signal voltage of the R-2R resistor network module and the theoretical voltage calculated by the R-2R algorithm module, and transmits the difference to the voltage regulation control module;
the voltage regulation control module is connected to the voltage compensation module, the voltage regulation control module and the voltage compensation module compensate the output voltage, so that the actual output voltage after compensation more closely matches the theoretical voltage value calculated by the R-2R algorithm module, thereby reducing the delay caused during voltage detection and voltage comparison;
after compensating the output voltage of the R-2R resistor network module, the compensated voltage is output via the output interface;
in a case that it is in the audio playback mode:
the I2S audio interface receives an externally input digital audio signal, the R-2R resistor network module converts the sweep digital signal into an analog signal, thereby achieving digital-to-analog conversion, wherein the output analog voltage passes through the precision voltage detection module to reach the voltage compensation module;
the R-2R algorithm module comprises an embedded R-2R algorithm that calculates, after a sweep digital signal is input into an error-free R-2R resistor network module, a theoretical voltage output of the error-free R-2R resistor network module based on the sweep digital signal input;
the precision voltage detection module performs precise detection of the output signal voltage from the R-2R resistor network module and inputs the output signal voltage along with the theoretical voltage value calculated by the R-2R algorithm module into the voltage comparison module for voltage comparison;
the voltage comparison module calculates a difference between the output signal voltage of the R-2R resistor network module and the theoretical voltage calculated by the R-2R algorithm module, and transmits the difference to the voltage regulation control module;
the voltage regulation control module is connected to the voltage compensation module, the voltage regulation control module and the voltage compensation module compensate the output voltage, so that the actual output voltage after compensation more closely matches the theoretical voltage value calculated by the R-2R algorithm module, thereby reducing the delay caused during voltage detection and voltage comparison;
after compensating the voltage output from the R-2R resistor network module, the voltage is output via the output interface.
